(19) United States
(12) Patent Application Publication
(10) Pub. No.: US 2015/0115273 A1
(43) Pub. Date: Apr. 30, 2015

(54) ARRAY SUBSTRATE, METHOD FOR MANUFACTURING THE SAME AND DISPLAY DEVICE

(71) Applicant: BOE TECHNOLOGY GROUP CO., LTD., Beijing (CN)

(72) Inventor: Liangchen Yan, Beijing (CN)

(73) Assignee: BOE TECHNOLOGY GROUP CO., LTD., Beijing (CN)

(21) Appl. No.: 14/367,780

(22) PCT Filed: Dec. 18, 2013
(86) PCT No.: PCT/CN2013/089744

§ 371 Date: Jun. 20, 2014

(30) Foreign Application Priority Data
Jul. 30, 2013 (CN) 201310326058.0

(51) Int. Cl. H01L 29/51; H01L 21/28; H01L 27/12; H01L 29/66

(52) U.S. Cl. CPC H01L 29/517; H01L 29/66765; H01L 21/28176; H01L 27/1237
USPC 257/72; 438/287

(57) ABSTRACT

The present invention provides an array substrate, a method for manufacturing the array substrate and a display device, and belongs to a field of display technology. A gate electrode and a gate line of the array substrate are coated with a metal oxide thin film. By applying the technical scheme of the present invention, diffusion of a metal atom of the gate electrode and the gate line is prevented in the array substrate.

### CROSS-REFERENCE TO RELATED APPLICATION

This application is the U.S. national phase of PCT Application No. PCT/CN2013/089744 filed on Dec. 18, 2013, which claims priority to Chinese Patent Application No. 201310326058.0 filed on Jul. 30, 2013, the disclosures of which are incorporated in their entirety by reference herein.

### TECHNICAL FIELD

The present invention relates to a field of display technique, and in particular relates to an array substrate, a method for manufacturing the array substrate, and a display device.

### BACKGROUND

Along with continuous improvement of technology, a user's requirement for a liquid crystal display device is increasing and a thin film transistor-liquid crystal display (TFT-LCD) has also become a popular display used in a product such as a mobile phone, a tablet computer, etc.

Display quality of the liquid crystal display device is determined by performance of the TFT. FIG. 1 is a structural view of an existing TFT array substrate. As shown in FIG. 1, the existing TFT array substrate generally includes a substrate 1, a gate electrode and a gate line 11, a gate insulating layer 5, an active layer 6, an etching barrier layer 7, a source electrode and drain electrode 8, a passivation layer 9 and a pixel electrode 10 in turn. In order to improve an electrical conductivity of the gate electrode and the gate line, the gate electrode and the gate line are generally prepared from Cu. However, after the gate electrode and the gate line are prepared from Cu, a Cu atom of the gate electrode and the gate line diffuses easily, and because compactness of the gate insulating layer is not good, the Cu atom may enter into the active layer through the gate insulating layer, thereby increasing the electrical conductivity of the active layer, and thus the performance of the TFT may be seriously influenced, resulting in that the display device cannot normally display.

### SUMMARY

The technical problem to be solved by the present invention is to provide an array substrate, a method for manufacturing the array substrate and a display device, which can avoid diffusion of a metal atom of a gate electrode and a gate line in the array substrate.

In order to solve the above technique problem, a technical scheme provided by an embodiment of the present invention is described below.

In one aspect, an array substrate is provided, wherein a gate electrode and a gate line of the array substrate are coated with a metal oxide thin film.

Further, in the above technical scheme, the metal oxide thin film is formed by a second metal in a gate metal layer reacting with oxygen, said gate metal layer containing a first metal and the second metal.

Further, in the above technical scheme, the gate electrode and the gate line coated with the metal oxide thin film are obtained by using the gate metal layer to form a pattern of the gate electrode and the gate line and annealing the pattern of the gate electrode and the gate line in a gas containing oxygen.

Further, in the above technical scheme, the first metal is Cu and the second metal is at least one of Mg, Cr, Hf, Ca, and Al.

Further, in the above technical scheme, the second metal accounts for 1-5 wt % of the gate metal layer.

Further, in the above technical scheme, the array substrate specifically comprises:

a substrate,

the gate electrode and the gate line coated with the metal oxide thin film on the substrate,

a gate insulating layer on the gate electrode and the gate line coated with the metal oxide thin film,

an active layer on the gate insulating layer,

an etching barrier layer on the active layer,

a drain electrode, a source electrode and a data line, formed from a source-drain metal layer on the etching barrier layer,

a passivation layer on the drain electrode, the source electrode and the data line, said passivation layer comprising a via hole corresponding to the drain electrode,

a pixel electrode on the passivation layer, said pixel electrode electrically connected with the drain electrode through the via hole.

The embodiment of the present invention also provides a display device, comprising the above array substrate.

The embodiment of the present invention also provides a method for manufacturing the array substrate, comprising:

segregating a second metal contained in a gate metal layer from the first metal, said gate metal layer containing,

making the second metal react with outside oxygen to form the metal oxide thin film on an external surface of the gate electrode and the gate line.

Further, in the above technical scheme, after a pattern of the gate electrode and the gate line is formed by using the gate metal layer, the pattern of the gate electrode and the gate line is annealed in a gas containing oxygen and the second metal is segregated from the first metal and reacts with outside oxygen, thereby forming the metal oxide thin film on the external surface of the gate electrode and the gate line.

Further, in the above technical scheme, the first metal is Cu and the second metal is at least one of Mg, Cr, Hf, Ca, and Al.

Further, in the above technical scheme, a step of annealing of the pattern of the gate electrode and the gate line in the gas containing oxygen comprising:

annealing the pattern of the gate electrode and the gate line in a temperature of 200-300° C. for 0.5-2 hours.

Further, in the above technical scheme, the method for manufacturing the array substrate specifically comprising:

providing a substrate;

forming the pattern of the gate electrode and the gate line on the substrate by using the gate metal layer, and annealing the pattern of the gate electrode and the gate line in the gas containing oxygen, thereby obtaining the gate electrode and the gate line coated with the metal oxide thin film,

forming a gate insulating layer on the substrate having the gate electrode and the gate line coated with the metal oxide thin film,

forming a pattern of an active layer on the substrate having the gate insulating layer,

forming a pattern of a etching barrier layer on the substrate having the active layer,

forming a pattern of a data line, a source electrode and a drain electrode on the substrate having the etching barrier layer;

forming a pattern of the passivation layer on the substrate having the data line, the source electrode and the drain electrode, wherein the pattern of the passivation layer comprises a via hole corresponding to the drain electrode, and

forming a pattern of the pixel electrode on the substrate having the passivation layer, wherein the pixel electrode is electrically connected with the drain electrode through the via hole.

The embodiment of the present invention has the following advantages:

In the above technical scheme, the gate electrode and the gate line of the array substrate are coated with the metal oxide thin film, diffusion of the metal atom of the gate electrode and the gate line into other areas of the array substrate is effectively prevented, and thus the performance of the TFT cannot be influenced, and the display can normally display.

### BRIEF DESCRIPTION OF THE DRAWINGS

FIG. 1 is a structural view showing a TFT array substrate according to the prior art,

FIG. 2 is a sectional view showing the substrate having a gate electrode and a gate line according to an embodiment of the present invention,

FIG. 3 is a sectional view showing the array substrate after the gate electrode and the gate line on the array substrate are annealed according to an embodiment of the present invention,

FIG. 4 is a sectional view showing the array substrate after the gate insulating layer is formed on the array substrate according to an embodiment of the present invention,

FIG. 5 is a sectional view showing the array substrate after the pattern of the active layer is formed on the array substrate according to an embodiment of the present invention,

FIG. 6 is a sectional view showing the array substrate after the pattern of the etching barrier layer is formed on the array substrate according to an embodiment of the present invention,

FIG. 7 is a sectional view showing the array substrate after the source-drain metal layer is formed on the array substrate according to an embodiment of the present invention,

FIG. 8 is a sectional view showing the array substrate after a source electrode, a drain electrode and a date line are formed on the array substrate according to an embodiment of the present invention,

FIG. 9 is a sectional view showing the array substrate after the pattern of the passivation layer is formed on the array substrate according to an embodiment of the present invention,

FIG. 10 is a sectional view showing the array substrate after the pixel electrode is formed on the array substrate according to an embodiment of the present invention.

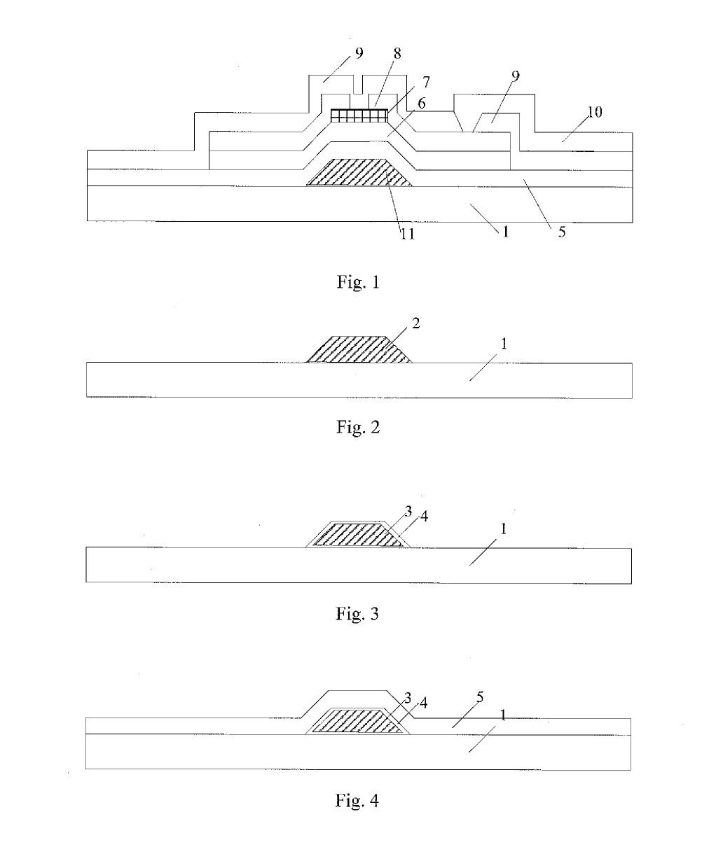

### LIST OF REFERENCE

1, a substrate 2, a gate electrode layer 3, a metal electrical conductive portion 4, a metal oxide thin film 5, a gate insulating layer 6, an active layer 7, an etching barrier layer 8, a source-drain metal layer 9, a passivation layer 10, a pixel electrode

### DETAILED DESCRIPTION

In order to make the technical problem to be solved by embodiments of the present invention and the technical scheme and the advantage of the present invention clearer, a detailed description will be shown below in combination with the appended drawings and the following embodiments.

The embodiment of the present invention relates to the problem that in the prior art a Cu atom of a gate electrode and a gate line diffuses easily and enters into an active layer through a gate insulating layer, which increases electrical conductivity of the active layer and seriously influences performance of the TFT, resulting in that a display cannot normally display. The embodiment of the present invention provides an array substrate, a method for manufacturing the array substrate and a display device, wherein a metal atom of the gate electrode and the gate line is prevented from diffusing in the array substrate.

The embodiment of the present invention provides an array substrate, wherein a gate electrode and a gate line of the array substrate are coated with a metal oxide thin film. Because the metal oxide thin film is compact, the metal oxide thin film can efficiently prevent the metal atom of the gate electrode and the gate line from diffusing into other areas of the array substrate, and thus performance of a TFT cannot be influenced and normal display of the display is guaranteed.

Specifically, the metal oxide thin film is formed by reaction of a second metal in a gate metal layer with oxygen, said gate metal layer containing a first metal and the second metal.

More specifically, the gate electrode and the gate line coated with the metal oxide thin film are obtained by annealing a pattern of the gate electrode and the gate line in a gas containing oxygen after forming the pattern of the gate electrode and the gate line by using the gate metal layer.

In the present invention, the gate metal layer is an alloy layer containing the first metal and the second metal. The first metal is used as a main body of the gate electrode and the gate line. Generally, the first metal may be selected from a metal having good electrical conductivity, such as Cu, and the second metal is used to form the metal oxide thin film on external surface of the gate electrode and the gate line. Generally, the second metal may be selected from a metal which can react with oxygen easily, such as Mg, Cr, Hf, Ca, Al, etc. The second metal should not be limited to one kind of metal, but may be two, three, or more kinds of metals. After the pattern of the gate electrode and the gate line is formed from an alloy containing the first metal and the second metal, the gate electrode and the gate line are annealed in the gas containing oxygen. In a high temperature during the annealing, the second metal is segregated from the first metal and reacts with outside oxygen to form a compact layer of metal oxide thin film on external surface of the gate electrode and the gate line, thereby effectively preventing the metal atom of the gate electrode and the gate line from diffusing.

In the technical scheme of the present invention, a main function of the second metal is to form the metal oxide thin film, but is not to be used as the main body of the gate electrode and the gate line. Therefore, a proportion of the second metal in the gate metal layer is not required to be very high and generally is 1-5 wt % or less.

Specifically, the array substrate of the present invention comprises:

a substrate;

the gate electrode and the gate line coated with the metal oxide thin film on the substrate;

a gate insulating layer on the gate electrode and the gate line coated with the metal oxide thin film,

an active layer on the gate insulating layer,

an etching barrier layer on the active layer,

a drain electrode, a source electrode and a data line formed from a source-drain metal layer on the etching barrier layer,

a passivation layer on the drain electrode, the source electrode and the data line, said passivation layer comprising a via hole corresponding to the drain electrode,

a pixel electrode on the passivation layer, said pixel electrode electrically connected with drain electrode through the via hole.

The embodiment of the present invention also provides a display device, comprising the array substrate described in any one of the above embodiments. Wherein a structure of the array substrate is the same as that in the above embodiments, and will not be described here. Additionally, the structure of other parts of the display device may be known by referring to the prior art, and the details will not be described here. The display device may be: a product or a component having any display function, such as a liquid crystal panel, an electrical paper, a liquid crystal television, a liquid crystal display, a digital photo frame, a mobile phone, a tablet computer, etc.

The embodiment of the present invention also provides a method for manufacturing the array substrate, comprising: forming a gate electrode and a gate line coated with a metal oxide thin film. Because the metal oxide thin film coated on a external surface of the gate electrode and the gate line is compact, the metal oxide thin film can efficiently prevent a metal atom of the gate electrode and the gate line from diffusing into other areas of the array substrate, and thus the performance of the TFT cannot be influenced, and normal display of the display is guaranteed.

When forming the gate electrode and the gate line coated with the metal oxide thin film, the gate electrode and the gate line coated with the metal oxide thin film are obtained by depositing the metal oxide thin film on the gate electrode and the gate line and patterning after the gate electrode and the gate line are formed. This requires a high-level process and an increased manufacturing cost. Therefore, in the technical scheme of the present invention, the gate metal layer containing the first metal and the second metal is used to form the pattern of the gate electrode and the gate line, and then the pattern of the gate electrode and the gate line is annealed in the gas containing oxygen to segregate the second metal from the first metal and make the second metal react with the outside oxygen, and thus the metal oxide thin film is formed on the external surface of the gate electrode and the gate line.

In the method for manufacturing the array substrate according to the prevent invention, the gate electrode and the gate line coated with the metal oxide thin film can be obtained only by preparing the gate electrode and the gate line using the alloy containing the first metal and the second metal and annealing the pattern of the gate electrode and the gate line in the gas containing oxygen, without an additional patterning process. the metal atom of the gate electrode and the gate line is prevented from diffusing into other areas of the array substrate without increasing the manufacturing cost.

In the present invention, the gate metal layer is an alloy layer containing the first metal and the second metal. The first metal is used as a main body of the gate electrode and the gate line. Generally, the first metal may be selected from a metal having good electrical conductivity, such as Cu, and the second metal is used to form the metal oxide thin film on the external surface of the gate electrode and the gate line. Generally, the second metal may be selected from the metal which can react with oxygen easily, such as Mg, Cr, Hf, Ca, Al, etc. The second should not be limited to one kind of metal, but may be two, three, or more kinds of metals. After the pattern of the gate electrode and the gate line is formed from the alloy containing the first metal and the second metal, the gate electrode and the gate line are annealed in the gas containing oxygen. In the high temperature for the annealing, the second metal is segregated from the first metal and reacted with the outside oxygen, thereby forming a compact layer of metal oxide thin film on the external surface of the gate electrode and the gate line, and effectively preventing the metal atom of the gate electrode and the gate line from diffusing.

In the technical scheme of the present invention, a main function of the second metal is to form the metal oxide thin film, but is not to be used as the main body of the gate electrode and the gate line. Therefore, a weight percentage of the second metal in the gate metal layer is not required to be very high, and generally is 1-5% or less.

Preferably, in one embodiment of the present invention, the first metal is Cu, the second metal may be Mg and Al, and the gate metal layer is a Cu alloy containing a small amount of Al and Mg. The Cu alloy containing the small amount of Al and Mg is deposited on the substrate, and the pattern of the gate electrode and the gate line is formed through the patterning process. Then, the pattern of the gate electrode and the gate line is annealed in the gas containing oxygen. Specifically, the annealing may be performed in pure oxygen in a temperature of 200-300° C. for 0.5-2 hours. The Al and the Mg aggregate on a surface of the gate electrode and the gate line due to segregation of the Al and the Mg from the Cu alloy, and react with the outside oxygen to generate Al₂O₃ and MgO, while a interior portion of the gate electrode and the gate line nearly completely becomes Cu. Because both Al₂O₃ and MgO are compact metal oxide, the diffusion of the Cu atom can be prevented efficiently, and thus a diffusion phenomenon of the Cu atom of the TFT array substrate is solved, and a thin film transistor having Cu gate electrode with a low resistance is obtained.

Specifically, the method for manufacturing the array substrate according to the present invention may comprise:

providing a substrate,

forming a pattern of the gate electrode and the gate line on the substrate by using a gate metal layer and annealing the pattern of the gate electrode and the gate line in the gas containing oxygen, to obtain the gate electrode and the gate line coated with the metal oxide thin film,

forming a gate insulating layer on the substrate having the gate electrode and the gate line coated with the metal oxide thin film,

forming a pattern of an active layer on the substrate having the gate insulating layer,

forming a pattern of a etching barrier layer on the substrate having the active layer,

forming a pattern of a data line, a source electrode and a drain electrode on the substrate having the etching barrier layer,

forming a pattern of the passivation layer on the substrate having the data line, the source electrode and the drain electrode, wherein the pattern of the passivation layer comprises a via hole corresponding to the drain electrode,

forming a pattern of a pixel electrode on the substrate having the passivation layer, wherein the pixel electrode is electrically connected with the drain electrode through the via hole.

The method for manufacturing the array substrate in this embodiment is further described below in combination with a specific process.

As shown in FIG. 2-10, the method for manufacturing the array substrate according to the present invention comprises the following steps.

Step a, providing a substrate 1, and forming a pattern of a gate electrode and a gate line formed from a gate metal layer 2 on the substrate 1.

As shown in FIG. 2, at first, the pattern of a gate electrode and a gate line connecting with the gate electrode formed from the gate metal layer 2 is formed on the substrate 1 through a single patterning process. Wherein, the substrate 1 may be a glass substrate or a quartz substrate.

Specifically, the gate metal layer 2 may be deposited on the substrate 1 by a method such as sputtering or thermal evaporation. The gate metal layer 2 is an alloy layer containing the first metal and the second metal. The first metal is used as the main body of the gate electrode and electrode line. Generally, the first metal may be selected from a metal having good electrical conductivity, such as Cu. The second metal is used to form the metal oxide thin film on the external surface of the gate electrode and the gate line. Generally, the second metal may be selected from the metal which can react with oxygen easily, such as Mg, Cr, Hf, Ca, Al, etc. The second metal is not limited to one kind of metal, but may be two, three or more kinds of metals. A photoresist is applied to the gate metal layer and the photoresist is exposed with the presence of a mask. a photoresist reserved area and a photoresist unreserved area are formed. Wherein the photoresist reserved area corresponds to an area in which the pattern of the gate electrode and the gate line is located and the photoresist unreserved area corresponds to an area other than the area in which the pattern of the gate electrode and the gate line is located. After a developing process, the photoresist unreserved area is completely removed, while a thickness of the photoresist reserved area remains unchanged. The gate metal layer in the photoresist unreserved area is completely etched though an etching process to form the pattern of the gate electrode and the gate line. The remaining photoresist is peeled off.

Step b: as shown in FIG. 3, annealing the pattern of the gate electrode and the gate line in the gas containing oxygen, to form the gate electrode and the gate line coated with the metal oxide thin film 4,

In a high temperature during the annealing, the second metal will be segregated from the first metal and reacts with outside oxygen, thereby forming a compact layer of metal oxide thin film 4 on external surface of the gate electrode and the gate line, and thus the diffusion of the metal atom of the gate electrode and the gate line is efficiently prevented. The main body of the gate electrode and the gate line is a metal electrical conductive portion 3. The metal electrical conductive portion 3 mainly comprises the first metal, or may also comprise a small part of the second metal which does not react with oxygen.

When the first metal is Cu and the second metal is Al and Mg, the gate metal layer is the Cu alloy layer containing a small amount of Al and Mg. Specifically, in the gas containing oxygen, the pattern of the gate electrode and the gate line is annealed in a temperature of 200-300° C. for 0.5-2 hours. In order to improve efficiency of forming the metal oxide thin film, preferably, the annealing may be performed in the pure oxygen. In the annealing, the Al and Mg aggregate on the surface of the gate electrode and the gate line due to the segregation of the Al and the Mg from the Cu alloy, and react with outside oxygen to generate Al₂O₃ and MgO, while the interior portion of the gate electrode and the gate line nearly completely becomes Cu. Because both Al₂O₃ and MgO are compact metal oxide, the diffusion of the Cu atom can be prevented efficiently.

Step c: as shown in FIG. 4, forming the gate insulating layer 5 on the substrate having the gate electrode and the gate line coated with the metal oxide thin film 4.

Specifically, a plasma enhanced chemical vapor deposition (PECVD) method may be adopted. A material for the gate insulating layer is deposited on the substrate undergoing the Step b in the thickness of 300 Å˜800 Å to form the gate insulating layer 5. Wherein the material for the gate insulating layer may be selected from an oxide, a nitride, or a nitrogen oxide, and the gate insulating layer may have a one-layer, two-layer or multiple-layer structure. The materials for different gate insulating layers are selected according to the materials for different active layers. For example, if the active layer adopts a-Si, then SiNx may be adopted to form the insulating layer, if the active layer is a metal oxide layer such as IGZO, etc., the insulating layer may be a compound layer structure such as SiOx, or SiOx/SiNx, or SiOx/SiON/SiNx or the like. In conclusion, the insulating layer and the Al₂O₃ and MgO formed on the external surface of the gate electrode and the gate line work together to prevent from a failure of the TFT device caused by diffusion of the Cu atom of the gate electrode and the gate line.

Step d: forming the pattern of the active layer 6 on the substrate on which the gate insulating layer 5 is formed.

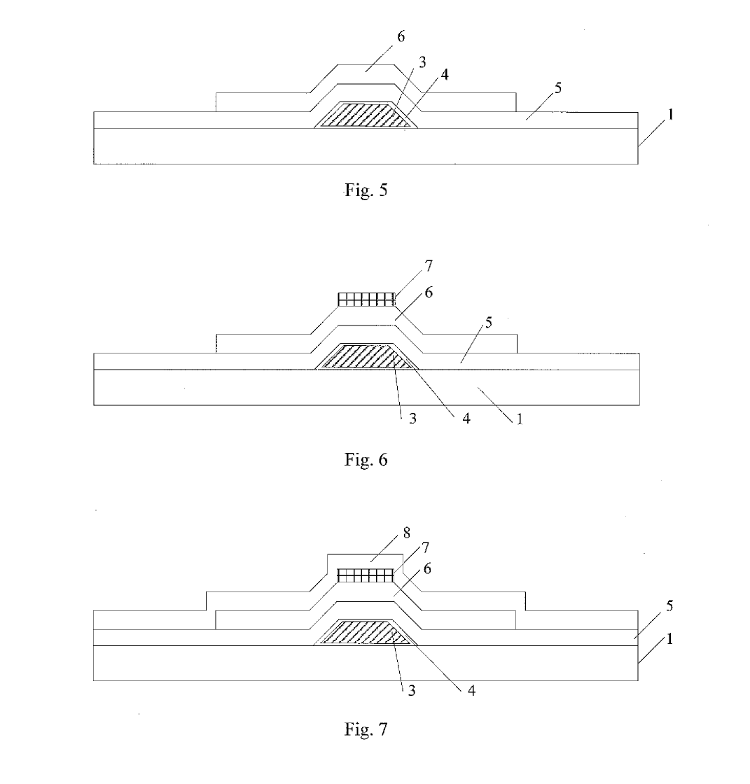

As shown in FIG. 5, specifically, a material for the active layer is deposited on the substrate undergoing the Step c by magnetron sputtering, thermal evaporation or other methods for forming a film. Then the photoresist is applied to the material for the active layer and the photoresist is exposed. A photoresist reserved area and a photoresist unreserved area are formed. After the developing process, the photoresist unreserved area is completely removed, while the thickness of the photoresist reserved area remains unchanged. The material for the active layer in the photoresist unreserved area is completely etched through an etching process to form the pattern of the active layer 6. The remaining photoresist in the photoresist reserved area is peeling off. Wherein the material of the active layer is selected from a-Si, IGZO, or other materials.

Step e: as shown in FIG. 6, forming the pattern of the etching barrier layer 7 on the substrate of the active layer 6.

Specifically, the material for the etching barrier layer is deposited on the substrate undergoing the Step d by the magnetron sputtering, the thermal evaporation or other methods for forming the film, wherein the material for the etching barrier layer may be selected from the oxide or the nitride. A photoresist is applied to the material for the etching layer, and the photoresist is exposed with the presence of a mask. A photoresist reserved area and a photoresist unreserved area are formed. Wherein the photoresist reserved area corresponds to the area in which the pattern of the etching barrier layer 7 is located and the photoresist unreserved area corresponds to the area other than the area in which the pattern of the etching barrier layer 7 is located. After developing process, the photoresist unreserved area is completely removed, while the thickness of the photoresist reserved area remains unchanged. The material for the etching barrier layer in the photoresist unreserved area is completely etched by the etching process to form the pattern of the etching battier layer 7. The remaining photoresist is peeling off.

Step f, as shown in FIGS. 7 and 8, forming the pattern of the source electrode, the drain electrode and the data line formed from the source-drain metal layer 8 on the substrate on which the etching barrier layer 7 is formed.

Specifically, source-drain metal layer 8 is deposited on the substrate undergoing the Step e by the magnetron sputtering, the thermal evaporation or other methods for forming the film. The material for the source-drain metal layer 8 may be a metal, such as Cr, W, Ti, Ta, Mo, Al, Cu, etc., or the alloy thereof. The source-drain metal layer 8 may also be multiple layers of the metal thin films. The photoresist is applied to the source-drain metal layer 8. The photoresist is exposed with the presence of the mask. A photoresist reserved area and a photoresist unreserved area are formed. Wherein the photoresist reserved area corresponds to the area in which the patterns of the source electrode, the drain electrode and the data line are located and the photoresist unreserved area corresponds to the area other than the area other than the area in which the patterns of the source electrode, the drain electrode and the data line are located. After developing process, the photoresist unreserved area is completely removed, while the thickness of the photoresist reserved area remains unchanged. The source-drain metal layer in the photoresist unreserved area is completely etched by the etching process to form the pattern of the source electrode, the drain electrode and the data line. The remaining photoresist is peeling off.

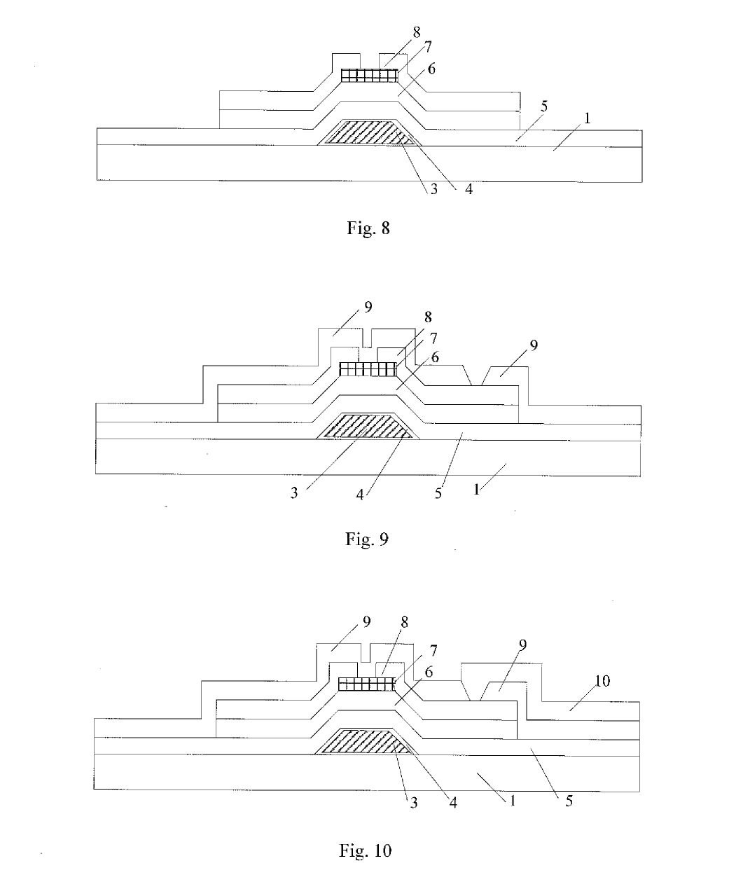

Step g: as shown in FIG. 9, forming the pattern of the passivation layer 9 on the substrate having the source electrode, the drain electrode and the data line.

Specifically, the material for the passivation layer is formed on the substrate undergoing the Step f in the thickness of 1500 Å˜2500 Å by the magnetron sputtering, the thermal evaporation or other methods for forming the film, wherein the material for the passivation layer may be selected from the oxide or the nitride. The photoresist is applied to the material for the passivation layer, and the photoresist is exposed with the presence of the mask. A photoresist reserved area and a photoresist unreserved area are formed. Wherein the photoresist reserved area corresponds to the area in which the pattern of the passivation layer is located and the photoresist unreserved area corresponds to the area other than the area in which the pattern of the passivation layer is located. After developing process, the photoresist unreserved area is completely removed, while the thickness of the photoresist reserved area remains unchanged. The material for the passivation layer in the photoresist unreserved area is completely etched by the etching process to form the pattern of the passivation layer 9. The remaining photoresist is peeling off.

Step h: as shown in FIG. 10, forming the pattern of the pixel electrode 10 on the substrate plate 1 on which the passivation layer 9 is formed and connecting the pixel electrode 10 with the drain electrode through the via hole.

Specifically, a transparent electrical conductive layer having the thickness of 300 Å˜600 Å is deposited on the substrate undergoing the step g, by the magnetron sputtering, the thermal evaporation or other methods for forming a film, wherein the transparent electrical conductive layer may use the material such as the indium tin oxide (ITO), the indium zinc oxide (IZO), etc. The photoresist is applied to the transparent electrical conductive layer, and the photoresist is exposed with the presence of the mask. A photoresist reserved area and a photoresist unreserved area are formed. Wherein the photoresist reserved area corresponds to the area in which the pattern of the pixel electrode 10 is located and the photoresist unreserved area corresponds to the area other than the area in which the pattern of the pixel electrode 10 is located. After developing process, the photoresist unreserved area is completely removed, while the thickness of the photoresist reserved area remains unchanged. The transparent electric conductive layer in the photoresist unreserved area is completely etched by the etching process to form the pattern of the pixel electrode 10. The remaining photoresist is peeling off.

The array substrate of this embodiment shown in FIG. 10 is obtained by adopting the above steps a-h. The gate electrode and the gate line of this embodiment are coated with the metal oxide thin film. Because the metal oxide thin film is compact, the metal atom of the gate electrode and the gate line is efficiently prevented from diffusing into other areas of the array substrate, and thus the performance of the TFT may not be influenced and the normal display of the display is guaranteed.

All those described above are only preferred embodiments of the present invention. It should be pointed out that several improvements and modifications may also be made by a person having ordinary skill in this art, without departing the principle of the present invention. These improvements and modification should also be regarded as the protection scope of the present invention.

All those described above are only preferred embodiments of the present invention. It should be pointed out that several improvements and modifications may also be made by a person having ordinary skill in this art, without departing the principle of the present invention. These improvements and modification should also be regarded as the protection scope of the present invention.

What is claimed is:

1. An array substrate, wherein a gate electrode and a gate line of the array substrate are coated with a metal oxide film.

2. The array substrate according to claim 1, wherein the metal oxide thin film is formed by a second metal in a gate metal layer reacting with oxygen, said gate metal layer containing a first metal and the second metal.

3. The array substrate according to claim 2, wherein the gate electrode and the gate line coated with the metal oxide thin film are obtained by using the gate metal layer to form a pattern of the gate electrode and the gate line and annealing the pattern of the gate electrode and the gate line in a gas containing oxygen.

4. The array substrate according to claim 2, wherein the first metal is Cu and the second metal is at least one of Mg, Cr, Hf, Ca, and Al.

5. The array substrate according to claim 2, wherein the second metal accounts for 1-5 wt % of the gate metal layer.

6. The array substrate according to claim 1, comprising:
a substrate,
the gate electrode and the gate line coated with the metal oxide thin film on the substrate,
a gate insulating layer on the gate electrode and the gate line coated with the metal oxide thin film,
an active layer on the gate insulating layer,
an etching barrier layer on the active layer,
a drain electrode, a source electrode and a data line formed from a source-drain metal layer on the etching barrier layer,
a passivation layer on the drain electrode, the source electrode and the data line, said passivation layer comprising a via hole corresponding to the drain electrode,
a pixel electrode on the passivation layer, said pixel electrode electrically connected with the drain electrode through the via hole.

7. The array substrate according to claim 2, comprising:
a substrate,
the gate electrode and the gate line coated with the metal oxide thin film on the substrate,
a gate insulating layer on the gate electrode and the gate line coated with the metal oxide thin film,
an active layer on the gate insulating layer,
an etching barrier layer on the active layer,
a drain electrode, a source electrode and a data line formed from a source-drain metal layer on the etching barrier layer,
a passivation layer on the drain electrode, the source electrode and the data line, said passivation layer comprising a via hole corresponding to the drain electrode,
a pixel electrode on the passivation layer, said pixel electrode electrically connected with the drain electrode through the via hole.

8. The array substrate according to claim 3, comprising:
a substrate,
the gate electrode and the gate line coated with the metal oxide thin film on the substrate,
a gate insulating layer on the gate electrode and the gate line coated with the metal oxide thin film,
an active layer on the gate insulating layer,
an etching barrier layer on the active layer,
a drain electrode, a source electrode and a data line formed from a source-drain metal layer on the etching barrier layer,
a passivation layer on the drain electrode, the source electrode and the data line, said passivation layer comprising a via hole corresponding to the drain electrode,
a pixel electrode on the passivation layer, said pixel electrode electrically connected with the drain electrode through the via hole.

9. The array substrate according to claim 4, comprising:
a substrate,
the gate electrode and the gate line coated with the metal oxide thin film on the substrate,
a gate insulating layer on the gate electrode and the gate line coated with the metal oxide thin film,
an active layer on the gate insulating layer,
an etching barrier layer on the active layer,
a drain electrode, a source electrode and a data line formed from a source-drain metal layer on the etching barrier layer,
a passivation layer on the drain electrode, the source electrode and the data line, said passivation layer comprising a via hole corresponding to the drain electrode,
a pixel electrode on the passivation layer, said pixel electrode electrically connected with the drain electrode through the via hole.

10. The array substrate according to claim 5, comprising:
a substrate,
the gate electrode and the gate line coated with the metal oxide thin film on the substrate,
a gate insulating layer on the gate electrode and the gate line coated with the metal oxide thin film,
an active layer on the gate insulating layer,
an etching barrier layer on the active layer,
a drain electrode, a source electrode and a data line formed from a source-drain metal layer on the etching barrier layer,
a passivation layer on the drain electrode, the source electrode and the data line, said passivation layer comprising a via hole corresponding to the drain electrode,
a pixel electrode on the passivation layer, said pixel electrode electrically connected with the drain electrode through the via hole.

11. A display device, comprising a array substrate, wherein a gate electrode and a gate line of the array substrate are coated with a metal oxide film.

12. The display device according to claim 11, wherein the metal oxide thin film is formed by a second metal in a gate metal layer reacting with oxygen, said gate metal layer containing a first metal and the second metal.

13. A method for manufacturing an array substrate, comprising:
segregating a second metal contained in a gate metal layer from a first metal, said gate metal layer containing the first metal and the second metal,
making the second metal react with outside oxygen to form the metal oxide thin film on an external surface of the gate electrode and the gate line.

14. The method for manufacturing the array substrate according to claim 13, wherein after a pattern of the gate electrode and the gate line is formed by using the gate metal layer, the pattern of the gate electrode and the gate line is annealed in a gas containing oxygen, and the second metal is segregated from the first metal and reacts with oxygen, thereby forming the metal oxide thin film on the external surface of the gate electrode and the gate line.

15. The method for manufacturing the array substrate according to claim 13, wherein the first metal is Cu and the second metal is at least one of Mg, Cr, Hf, Ca, and Al.

16. The method for manufacturing the array substrate according to claim 13, wherein a step of annealing the pattern of the gate electrode and the gate line in the gas containing oxygen comprising:
annealing the pattern of the gate electrode and the gate line in a temperature of 200-300° C. for 0.5-2 hours.

17. The method for manufacturing the array substrate according to claim 13, comprising:
providing a substrate,
forming the pattern of the gate electrode and the gate line on the substrate by using the gate metal layer, and annealing the pattern of the gate electrode and the gate line in the gas containing oxygen, thereby obtaining the gate electrode and the gate line coated with the metal oxide thin film,
forming a gate insulating layer on the substrate having the gate electrode and the gate line coated with the metal oxide thin film,
forming a pattern of an active layer on the substrate having the gate insulating layer,
forming a pattern of a etching barrier layer on the substrate having the active layer,
forming a pattern of a data line, a source electrode and a drain electrode on the substrate having the etching barrier layer,
forming a pattern of the passivation layer on the substrate having the data line, the source electrode and the drain electrode, wherein the pattern of the passivation layer comprises a via hole corresponding to the drain electrode, and
forming a pattern of a pixel electrode on the substrate having the passivation layer, wherein the pixel electrode is electrically connected with the drain electrode through the via hole.

18. The method for manufacturing the array substrate according to claim 14, comprising:
providing a substrate,
forming the pattern of the gate electrode and the gate line on the substrate by using the gate metal layer, and annealing the pattern of the gate electrode and the gate line in the gas containing oxygen, thereby obtaining the gate electrode and the gate line coated with the metal oxide thin film,
forming a gate insulating layer on the substrate having the gate electrode and the gate line coated with the metal oxide thin film,
forming a pattern of an active layer on the substrate having the gate insulating layer,
forming a pattern of a etching barrier layer on the substrate having the active layer,
forming a pattern of a data line, a source electrode and a drain electrode on the substrate having the etching barrier layer,
forming a pattern of the passivation layer on the substrate having the data line, the source electrode and the drain electrode, wherein the pattern of the passivation layer comprises a via hole corresponding to the drain electrode, and
forming a pattern of a pixel electrode on the substrate having the passivation layer, wherein the pixel electrode is electrically connected with the drain electrode through the via hole.

19. The method for manufacturing the array substrate according to claim 15, comprising:
providing a substrate,
forming the pattern of the gate electrode and the gate line on the substrate by using the gate metal layer, and annealing the pattern of the gate electrode and the gate line in the gas containing oxygen, thereby obtaining the gate electrode and the gate line coated with the metal oxide thin film,
forming a gate insulating layer on the substrate having the gate electrode and the gate line coated with the metal oxide thin film,
forming a pattern of an active layer on the substrate having the gate insulating layer,
forming a pattern of a etching barrier layer on the substrate having the active layer,
forming a pattern of a data line, a source electrode and a drain electrode on the substrate having the etching barrier layer,
forming a pattern of the passivation layer on the substrate having the data line, the source electrode and the drain electrode, wherein the pattern of the passivation layer comprises a via hole corresponding to the drain electrode, and
forming a pattern of a pixel electrode on the substrate having the passivation layer, wherein the pixel electrode is electrically connected with the drain electrode through the via hole.

20. The method for manufacturing the array substrate according to claim 16, comprising:
providing a substrate,
forming the pattern of the gate electrode and the gate line on the substrate by using the gate metal layer, and annealing the pattern of the gate electrode and the gate line in the gas containing oxygen, thereby obtaining the gate electrode and the gate line coated with the metal oxide thin film,
forming a gate insulating layer on the substrate having the gate electrode and the gate line coated with the metal oxide thin film,
forming a pattern of an active layer on the substrate having the gate insulating layer,
forming a pattern of a etching barrier layer on the substrate having the active layer,
forming a pattern of a data line, a source electrode and a drain electrode on the substrate having the etching barrier layer,
forming a pattern of the passivation layer on the substrate having the data line, the source electrode and the drain electrode, wherein the pattern of the passivation layer comprises a via hole corresponding to the drain electrode, and
forming a pattern of a pixel electrode on the substrate having the passivation layer, wherein the pixel electrode is electrically connected with the drain electrode through the via hole.
